(19) United States
(12) Patent Application Publication
(10) Pub. No.: US 2005/0079669 A1
(43) Pub. Date: Apr. 14, 2005

(54) Method of producing a capacitor in a dielectric layer

(75) Inventor: Klaus Goller, Dresden (DE)

Correspondence Address: Maginot, Moore & Beck;Bank One Tower, Suite 3000, 111 Monument Circle, Indianapolis, IN, 46204, US

(73) Assignee: Infineon Technologies AG, Munchen (DE)

(21) Appl. No.: 10/898,672

(22) Filed: Jul. 23, 2004

Related U.S. Application Data
(63) Continuation of application No. PCT/EP03/00671, filed on Jan. 23, 2003.

(30) Foreign Application Priority Data
Jan. 24, 2002 (DE) 10202697.1-33

(51) Int. Cl. H01L 21/8242

(52) U.S. Cl. 438/243; 438/386

(57) ABSTRACT

In a method of producing a capacitor in a first dielectric layer, a recess is formed in a surface of the first dielectric layer. On the surface of the first dielectric layer and in the recess a first conductive layer is formed. On the first conductive layer a second dielectric layer is formed, the sum of a thickness of the first conductive layer and of a thickness of the second dielectric layer in the recess being smaller than a depth of said recess. A second conductive layer is formed on the second dielectric layer. The capacitor is obtained by planarizing the thus formed layer structure.

### CROSS-REFERENCE TO RELATED APPLICATION

This application is a continuation of copending International Application No. PCT/EP03/00671, filed Jan. 23, 2003, which designated the United States and was not published in English, and is incorporated herein by reference in its entirety.

### BACKGROUND OF THE INVENTION

1. Field of the Invention

The present invention relates to a method of producing a capacitor and, in particular, to a method of producing a capacitor which is suitable for integrating a capacitor in an intermediate dielectric between two wiring planes.

2. Description of Prior Art

For producing capacitors in integrated circuits, a large number of techniques is known, the capacitance of a capacitor being determined by the surface of its electrodes, the distance at which these electrodes are located from one another and the permittivity ratio, i.e. the relative dielectric constant ∈ᵣ of a dielectric layer between the electrodes. In order to achieve a desired high capacitance on the basis of an electrode area which is as small as possible, the smallest possible distance between the electrodes and the smallest possible thickness of the dielectric layer between the electrodes, respectively, are especially necessary in addition to a high relative dielectric constant ∈ᵣ.

In conventional methods it is normally necessary to laterally structure the electrodes and the dielectric layer between the electrodes during the production of the capacitor, such lateral structuring being effected e.g. by means of a positive photoresist mask and an etching step or by means of a negative photoresist mask, which is applied prior to the respective layer, and a lift-off step. In the case of any kind of lateral structuring of a layer, the layer to be structured has to satisfy greater or less requirements on chemical and mechanical robustness, since, during the structuring, this layer will at least be exposed to a solvent for the photoresist mask even in the areas which are not to be removed. If a positive photoresist mask is used as an etching mask, the layer to be structured is additionally subjected to a mechanical contact with the photoresist and an exposure mask. The resultant, manufacturing technology-dependent requirements on the robustness of the layers to be structured entail restrictions as far as the selection of the materials is concerned and necessitate minimum thicknesses of the layers.

In the case of a dielectric layer these requirements set undesired limits to an increase of the capacitance of the capacitor and vice versa to the reduction of the electrode area of the capacitor by the use of a thinner dielectric layer.

Another problem is to be seen in that a dielectric layer projecting laterally below the upper capacitor plate will reduce the absorption properties of an anti-reflection coating (ARC; ARC=Anti Reflex Coating) located therebelow. This is disadvantageous during a subsequent exposure step.

Another disadvantage of the conventional production of a capacitor is to be seen in that separate lithographic and etching steps are necessary for structuring the upper capacitor plate.

### SUMMARY OF THE INVENTION

It is the object of the present invention to create an improved method of producing a capacitor in a dielectric layer.

In accordance with a first aspect, the present invention provides a method of producing a capacitor in a first dielectric layer, said method having the following steps: forming a recess in a surface of the first dielectric layer; producing a first conductive layer on the surface of the first dielectric layer and in the recess; producing a second dielectric layer on the first conductive layer, the sum of a thickness of the first conductive layer and of a thickness of the second dielectric layer in the recess being smaller than a depth of said recess; producing a second conductive layer on the second dielectric layer; planarizing the thus formed layer structure so as to obtain the capacitor; and producing a trench which completely surrounds the second electrode laterally and extends to the first conductive layer.

The present invention is based on the finding that, under specified conditions, it is possible to produce a capacitor in a recess in a first dielectric layer by producing in this recess a layer sequence consisting of two conductive layers and an intermediate dielectric layer and by executing then a planarizing step down to the surface of the first dielectric layer. This has the effect that the layer sequence is laterally structured, whereby the capacitor is formed. It has been recognized that this production method can especially be executed when the depth, i.e. the vertical dimensions of the recess are larger than the thickness of the first conductive layer to be deposited thereon and when the lateral dimensions of the recess are larger than twice the thickness of the first conductive layer.

The present invention is additionally based on the finding that the standard deposition of tungsten (T) for filling via holes can be used for producing via hole contacts, so as to produce the first conductive layer. In this case, the lateral and vertical dimensions of the recess have to be defined such that the recess is not filled completely by the tungsten layer applied for filling the via holes.

One advantage is to be seen in the fact that especially the second dielectric layer need not be structured separately prior to producing the second conductive layer on top of said second dielectric layer and that it is therefore not necessary to expose this second dielectric layer to a photoresist or to a solvent for this photoresist nor is it necessary to bring it into contact with an exposure mask. On the contrary, the second dielectric layer and the second conductive layer can be produced immediately one after the other. This has the effect that the second dielectric layer is packed in a sandwich-like manner during processing and protected against process influences. This will especially avoid a direct or an indirect etch attack on the second dielectric layer, and it is even possible to avoid any kind of contact of the second dielectric layer with an atmosphere. The thickness of the second dielectric layer can therefore easily be reduced to an almost arbitrary extent, and, in extreme cases, this second dielectric layer may have a thickness of only one or a few atomic layers, since said dielectric layer need not fulfil any requirements on mechanical or chemical robustness.

The second dielectric layer is produced on the first conductive layer preferably over the full area thereof.

With respect to the lateral embedment in a dielectric layer, a capacitor produced in accordance with the present invention is also referred to as GOLCAP (GOLCAP=GlObal Layered CAPacity).

Another advantage of the present invention is to be seen in the fact that, by planarizing the layer structure, the second conductive layer and, in addition, optionally the second dielectric layer and the first conductive layer can be structured laterally in a single method step. Hence, no further step is necessary for laterally structuring the layers, especially the upper capacitor plate, from the second conductive layer, whereby the investment in apparatus and process technology which is necessary for producing the capacitor will be reduced.

A further advantage resides in the fact that the method according to the present invention can be integrated with the production of via hole conductors so that it is e.g. possible to produce a via hole conductor in the first dielectric layer and the first conductive layer in a single step. Also the step of planarizing the layer structure can preferably be carried out in the same step in which the filling of the via holes is planarized. This will minimize the outlay for producing the capacitor.

Another advantage of the present invention is to be seen in the fact that the resultant well shape of the second dielectric layer and thus the lateral and vertical structural designs of the capacitor plates and electrodes, respectively, leads, in comparison with a purely planar structural design of a dielectric layer, to an increase in the electrode area and thus to an increase in the effective capacitance.

Another advantage is that both capacitor plates can be contacted in the same metal plane, i.e. in the same conductor layer. Furthermore, additional stop layers can be dispensed with in the case of the present invention, such stop layers being normally used when the capacitor plates are being contacted.

In addition, high requirements on the (CMP) planarization of the first dielectric layer, which are normally entailed by flat T-electrodes (tungsten electrodes), are eliminated by the present invention. The conventional high requirements on lithography for structuring the lower capacitor plate do not have to be satisfied either.

According to a preferred embodiment the second dielectric layer is present on the surface produced by planarizing not in the form of a planar but in the form of a linear structure. This means that the second dielectric layer exists only on the electrically active area of the T-electrodes but not outside of said electrodes. Problems during a subsequent photoresist exposure caused by absorption properties which have been changed by the dielectric layer are avoided in this way.

### BRIEF DESCRIPTION OF THE DRAWINGS

In the following preferred embodiments will be explained in detail making reference to the figures enclosed, in which:

FIG. 1 to 11 show schematic sectional views for explaining a method according to a first embodiment of the present invention;

FIG. 12 shows a schematic sectional view of a capacitor which has been produced by a method according to an alternative embodiment of the present invention;

FIG. 13 shows a schematic top view of the capacitor of FIG. 12;

FIG. 14 to 19 show schematic sectional views for explaining a method according to a further alternative embodiment of the present invention;

FIG. 20 to 22 show schematic sectional views for explaining a method according to a further alternative embodiment of the present invention;

FIG. 23 to 25 show schematic sectional views of further alternative capacitors produced by methods according to the present invention; and

FIG. 26 to 30 show schematic sectional views for explaining a method according to a further alternative embodiment of the present invention.

### DESCRIPTION OF PREFERRED EMBODIMENTS

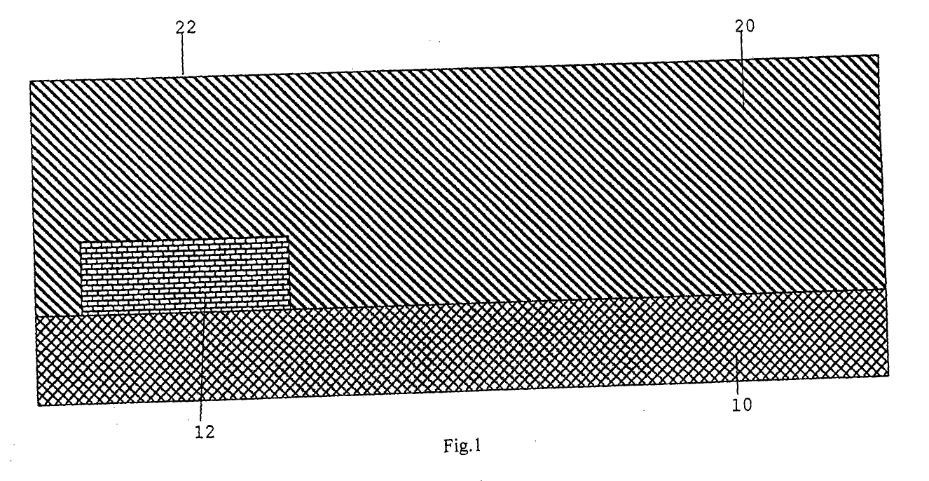

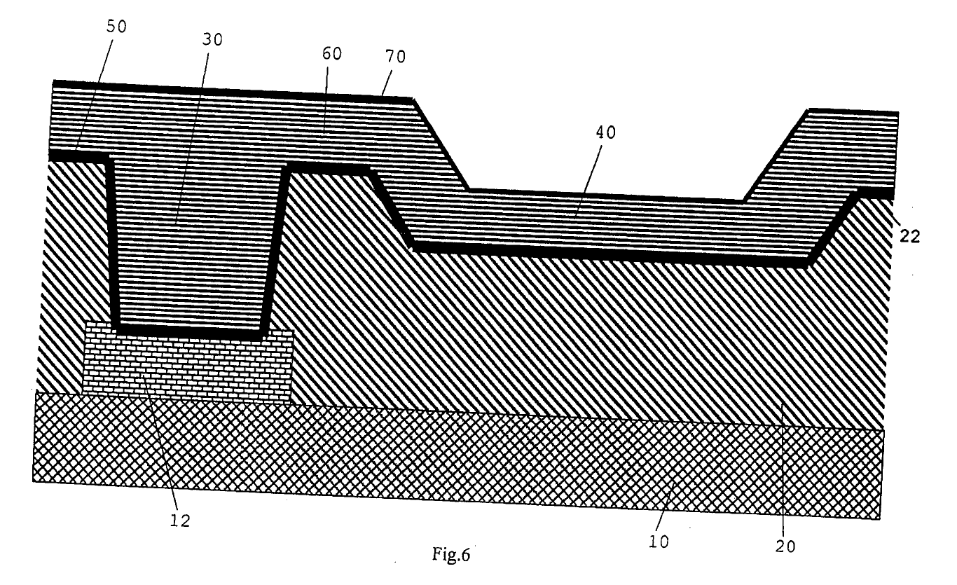

Making reference to FIG. 1 to 10, a first embodiment of the method according to the present invention will be explained in detail; in the case of this first embodiment, a capacitor is produced, partially together with a through-connection, in an intermediate dielectric between two wiring planes.

FIG. 1 shows a starting structure in which a conductor 12 is formed on a support layer 10. The support layer 10 can comprise e.g. a dielectric or a semiconductor material. The conductor 12 comprises a conductive material, e.g. aluminium or copper, and is provided as part of a wiring plane arranged on the support layer 10 and used for connecting components, which are not shown, in the support layer, said wiring plane being arranged on top of a component layer, which is not shown.

The first dielectric layer 20 is produced by applying to the support layer 10 a boron-phosphorus silicate glass (BPSG) or an oxide, which fills spaces between the conductor 12 and additional conductors, which are not shown, and covers said conductors. This results in a wavy surface which is then planarized by chemical-mechanical polishing (CMP) whereby the initially plane surface 22 of the first dielectric layer 20 is produced. The first dielectric layer 20 can be a dielectric layer between two wiring planes on top of a component layer of a semiconductor structure, e.g. a storage element or a microprocessor.

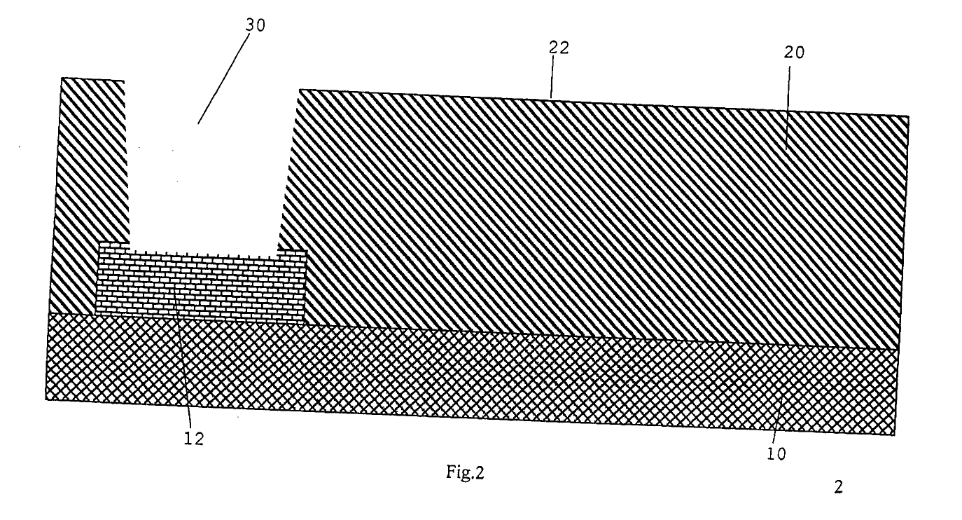

Starting from the structure shown in FIG. 1, a via hole for forming a via hole conductor is produced in the usual way, e.g. by means of a lithographic step or an etching step. The resultant structure is shown in FIG. 2. The via hole 30 extends from the surface 22 of the first dielectric layer 20 down to the conductor 12.

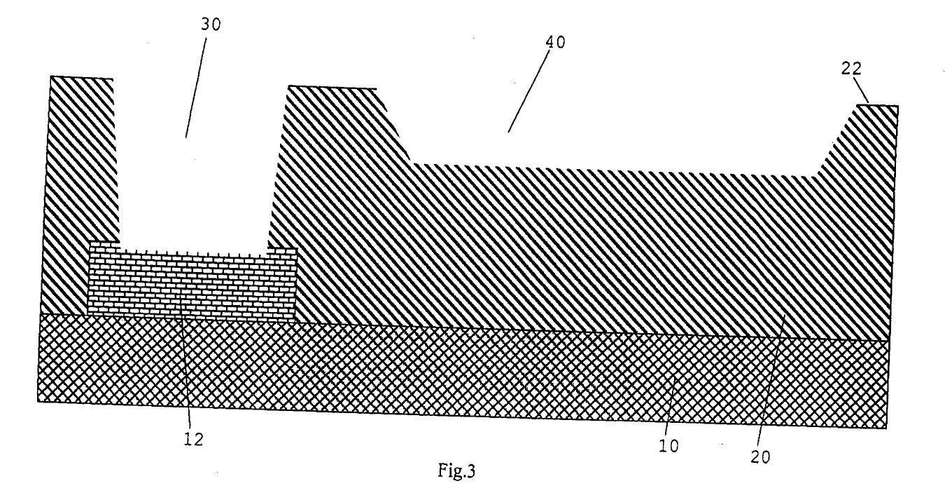

As shown in FIG. 3, a recess 40 is then formed in the surface 22 of the first dielectric layer 20 by a further lithographic step and a further etching step. In contrast to the via hole 30, which has a small cross-sectional area and a large depth, the recess 40 has a small depth in comparison with its lateral dimensions.

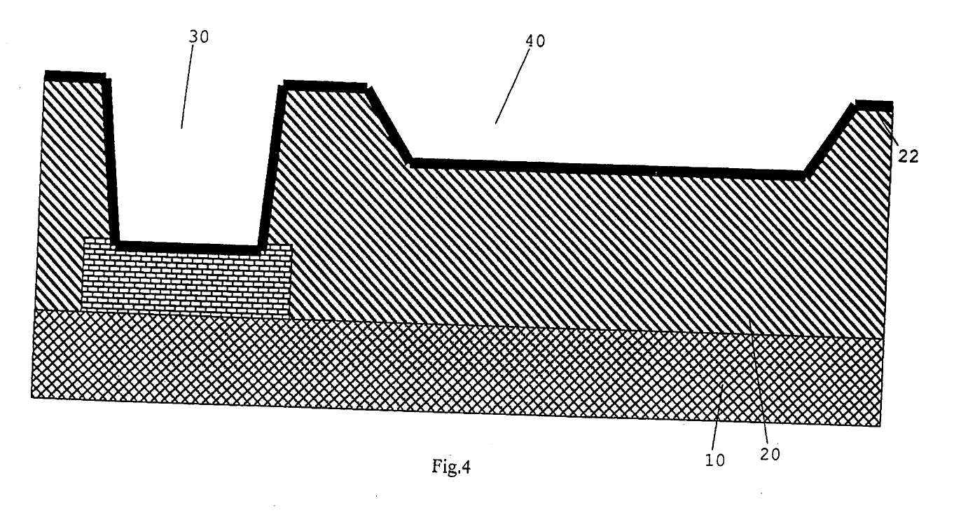

The surface 22 and the surfaces of the via hole 30 and of the recess 40 have applied thereto a thin liner or a thin intermediate layer 50, which is shown in FIG. 4. The intermediate layer 50 comprises Ti or TiN or some other liner sequence serving as a diffusion barrier and has preferably a thickness of approx. 50 nm.

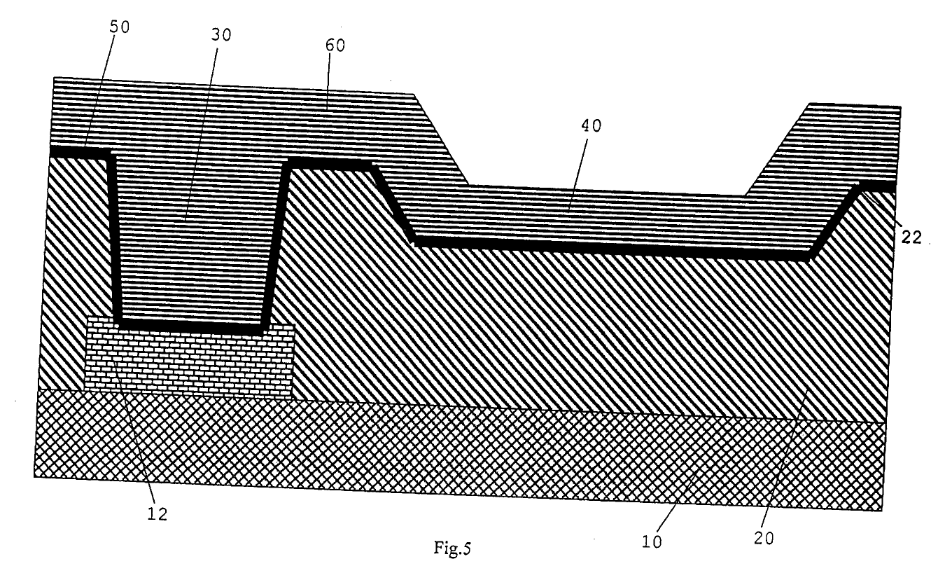

In the next step, a first T-layer 60 (T=tungsten) is produced on the intermediate layer 50. As can be seen in FIG. 5, the T-layer 60 completely fills the narrow and deep via hole 30. The intermediate layer 50 prevents a chemical reaction between the T of the first T-layer 60 and the material of the first dielectric layer 20 and/or adjusts the contact resistance between the T-layer 60 and the conductor 12 in the via hole 30.

The depth of the recess 40 is preferably larger than the thickness of the first T-layer 60 in said recess and the lateral dimensions of the recess 40 are larger than twice the thickness of the first T-layer 60. Under these preconditions, the recess 40 is, other than the via hole 30, not filled completely by the first T-layer 60, but the first T-layer 60 has essentially the same thickness within the recess 40 and outside of said recess 40 and of the via hole 30.

A thin second dielectric layer 70 comprising e.g. a nitride, oxide, tantalum oxide or aluminium oxide is produced on the first T-layer 60 over the full area thereof. The second dielectric layer 70 can have a thickness of e.g. 30 nm-50 nm. Preferably, it has, however, a very small thickness of 10 atomic layers or less and, according to a specially preferred embodiment, a thickness of only one, two or three atomic layers. It is produced by means of chemical vapour deposition (CVD), deposition of individual atomic layers from the gas phase (ALD; ALD=atomic layer deposition), or by means of some other method which is suitable for depositing such thin layers.

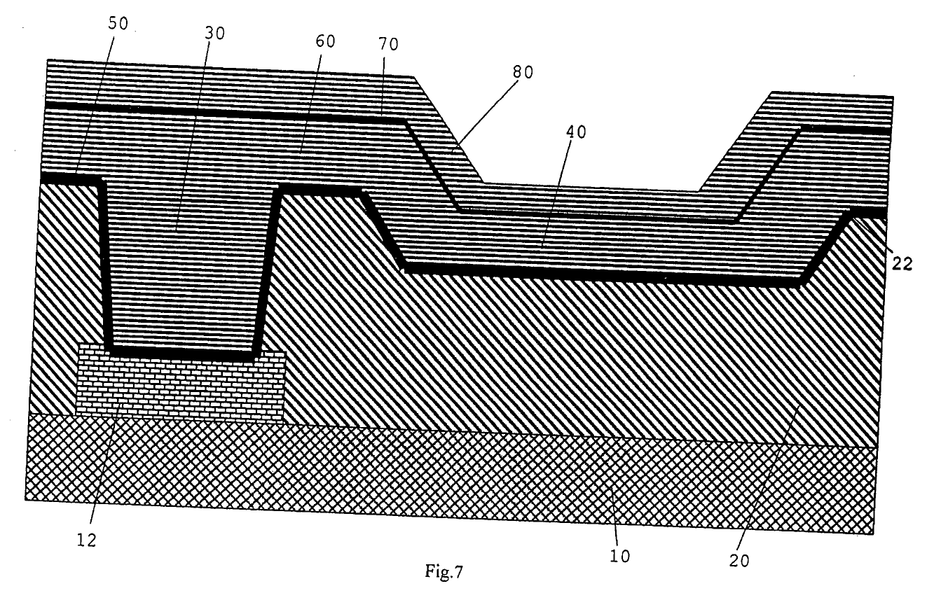

Preferably immediately after the production of the second dielectric layer 70, a second T-layer 80 is produced on top of the second dielectric layer 70., whereby the condition shown in FIG. 7 is obtained.

The fact that the second dielectric layer 70 and the second T-layer 80 are deposited immediately one after the other especially means that, prior to the production of the second T-layer 80, the second dielectric layer 70 is neither coated with a photoresist mask nor brought into mechanical contact with an exposure mask nor exposed to any solvent or etching bath nor subjected to an exposure. When the second dielectric layer 70 and the second T-layer 80 are produced within the same device or within the same (vacuum) receptacle, the second dielectric layer 70 will not be subjected to any influence of air or of a protective atmosphere. An influence of light on the second dielectric layer can easily be avoided as well. Furthermore, the period between the production of the second dielectric layer 70 and the production of the second T-layer 80 can be as short as desired. Hence, the second dielectric layer 70 need not satisfy any requirements with respect to chemical or mechanical robustness, light resistance or aging resistance. Insofar, no restrictions whatsoever exist as far as the selection of a material for the second dielectric layer 70 is concerned; on the contrary, an unlimited optimization is possible with respect to a minimum thickness, a maximum relative dielectric constant ∈ᵣ, a desired frequency dependence thereof, a high dielectric strength or a high breakdown electric field strength or other parameters which are important to a respective case of use.

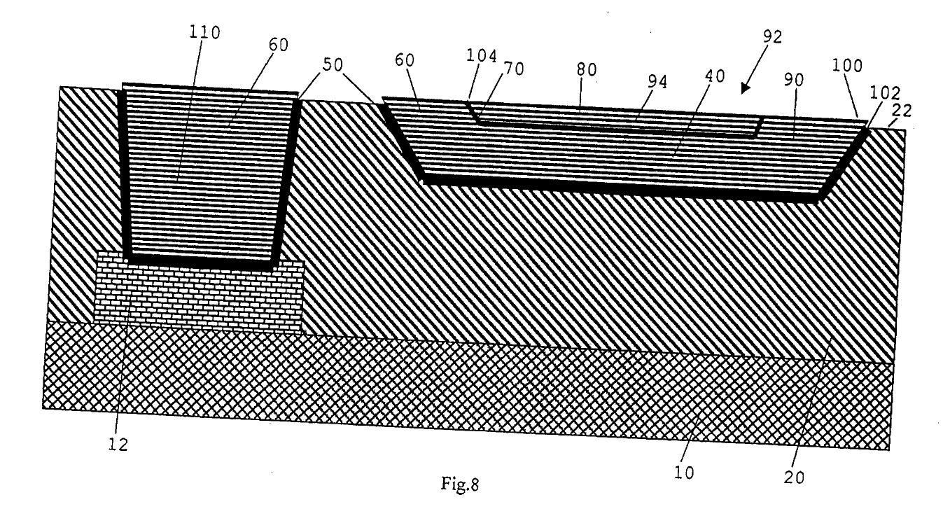

In a further method step, the layer structure shown in FIG. 7, which consists of the first T-layer 60, the second dielectric layer 70 and the second T-layer 80, is planarized by polishing, preferably by chemical-mechanical polishing. In this polishing step, the first intermediate layer 50, the first T-layer 60, the second dielectric layer 70 and the second T-layer 80 are removed outside of the via hole 30 and of the recess 40 essentially down to a plane defined by the original surface 22 of the first dielectric layer 20, as can be seen in FIG. 8. The remaining areas of the T-layers 60, 80 can slightly project beyond the first dielectric layer 20 in the vertical direction, as indicated in FIG. 8.

The thickness of the first T-layer 60 and the thickness of the second dielectric layer 70 are, in common, smaller than the thickness of the recess 40 so that, after the planarizing step, not only the first T-layer 60 but also the intermediate layer 50 and the second T-layer 80 partially remain in the recess 40. The remaining portion of the first T-layer 60 forms a first electrode 90 of a capacitor 92, the remaining portion of the second t-layer 80 forms a second electrode 94 of the capacitor 92, the first electrode 90 and the second electrode 94 of the capacitor 92 being spatially separated and electrically insulated from one another by a remaining portion 96 of the second dielectric layer 70. The lateral dimensions of the electrodes 90, 94 and thus their areas and the capacitance of the capacitor 92 are determined by the area of the portion 96 of the second dielectric layer 70 and therefore essentially by the lateral dimensions of the recess 40. In particular, an edge 100 of the first electrode 90 essentially corresponds to an edge 102 of the recess 40. An edge 104 of the second electrode 94 is located at a distance from the edge 102 of the recess 40 which is essentially determined by the thickness of the first T-layer 60, the depth of the recess 40 and an inclination of the side wall of the recess 40.

A portion of the first T-layer 60 remaining in the via hole 30 forms a via hole conductor 110. By means of the planarizing step, especially the intermediate layer 50 and the first T-layer 60 are removed in an area between the via hole 30 and the recess 40 so that, initially, there is no conductive connection between the via hole conductor 110 and the first electrode 90 of the capacitor 92. In order to guarantee this, also part of the first dielectric layer 20 is preferably removed during the planarizing step so that, after the planarizing step, the surface 22 of the first dielectric layer 20 can be located on a lower level, i.e. closer to the support layer 10.

The formation of the capacitor 92 is now finished. In the subsequent method steps, contact pads and conductors are produced for wiring,

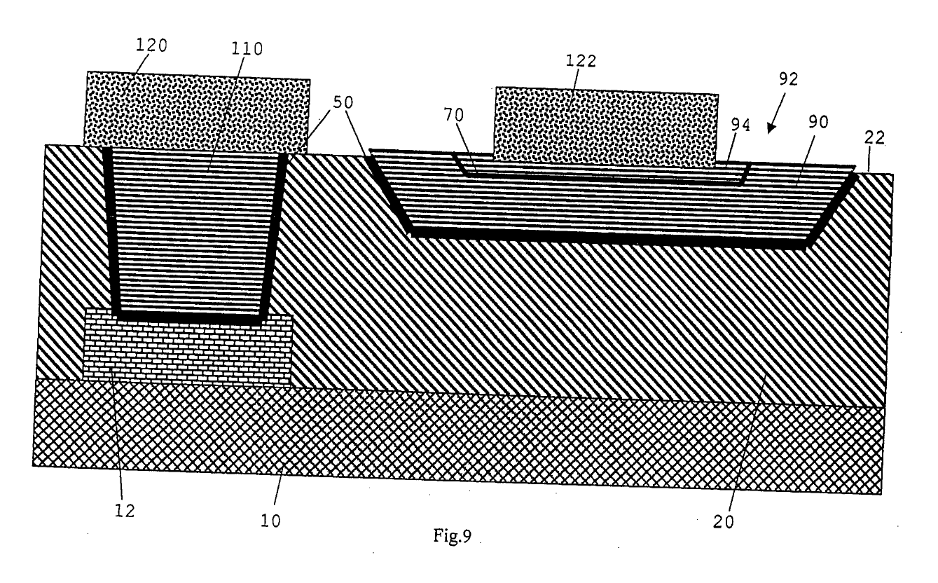

In FIG. 9, a conductor 120 on the via hole conductor 110 and a conductor 122 on the second electrode 94 of the capacitor 92 are shown. Whereas, as shown in the figure, the conductor 120 can be broader than the via hole conductor 110 and can therefore cover the surface 22 of the dielectric layer 20 in the surroundings of the via hole conductor 110, the conductor 122 is exclusively provided on the second electrode 94 of the capacitor 92.

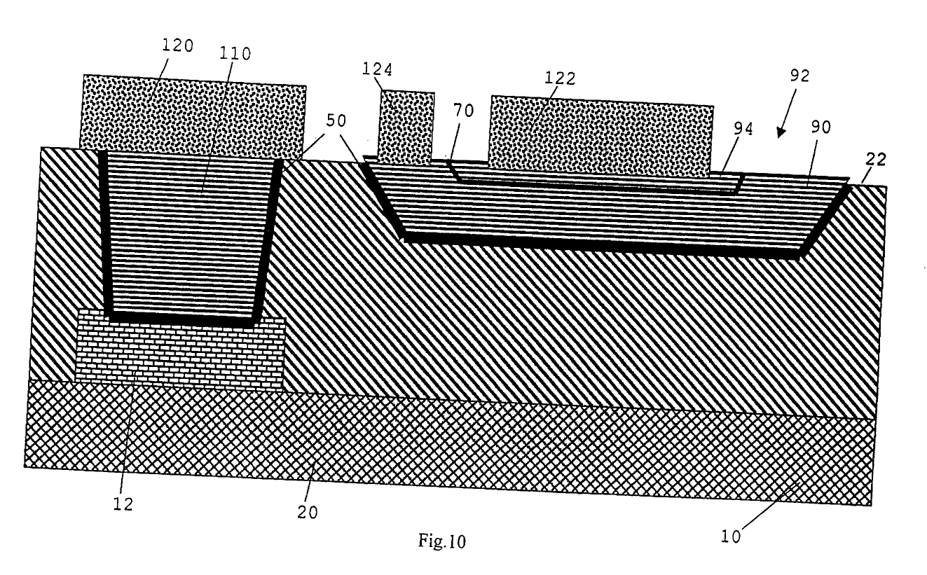

In FIG. 10, the first electrode 90 of the capacitor 92 is additionally contacted to a further conductor 124. This further conductor 124 can be produced simultaneously with the conductors 120, 122 or in separate method steps.

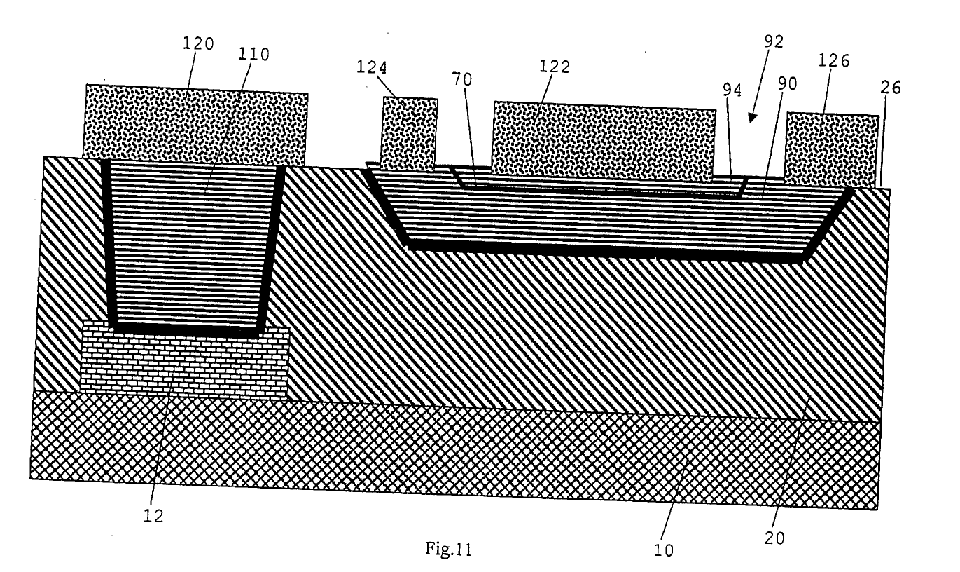

Alternatively, the first electrode 90 of the capacitor 92 is additionally shown with a further conductor 126 in FIG. 11. The conductors 120, 122, 124, 126 are produced from an electrically conductive material, preferably Al or Cu, and can be produced in common or separately.

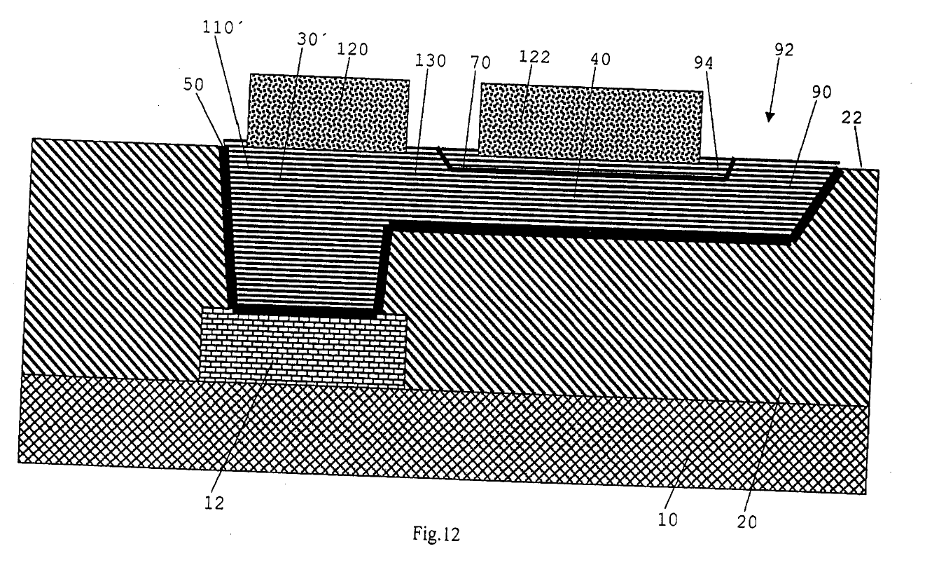

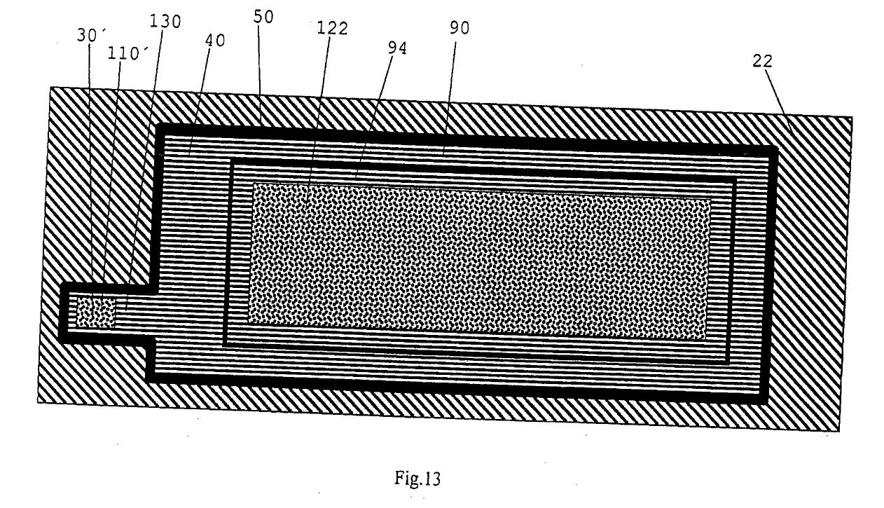

FIG. 12 shows a schematic sectional view of a capacitor 92, which was produced according to an alternative embodiment of the method according to the present invention, and FIG. 13 shows a schematic top view of this capacitor 92. This embodiment differs from the embodiment shown on the basis of FIG. 1 to 11 insofar as the first electrode 90 of the capacitor 92 and a via hole conductor 110′ are directly interconnected via a T-bridge. The recess 40 is provided with a projecting portion 130 for this purpose, said projecting portion 130 having provided therein a via hole 30′. The width and the depth of the projecting portion 130 of the recess 40 are chosen so small that, when the production of the first T-layer 60 shown on the basis of FIG. 5 takes place, the projecting portion 130 will, similar to the via hole 30, be filled completely by this first T-layer 60. It follows that, after the execution of the method steps described with reference to FIG. 1 to 9, the first electrode 90 of the capacitor 92 is integrally connected to the via hole conductor 110′ via a T-bridge. In addition, the conductor 120, which also contacts the first electrode of the capacitor 92, is provided on top of the via hole conductor 110′. Due to the projecting portion 130, more space for contacting the first electrode 90 on the surface 22 of the dielectric layer 20 is provided. The geometry of the recess 40 with the projecting portion 130 shown in the figure is therefore advantageous for contacting the first electrode 90 by means of the conductor 12 on the support layer 10 as well as for contacting the first electrode 90 by means of the conductor 120 on the surface 22 of the dielectric layer 20. Deviating from the representation in FIG. 12, the first electrode 90 may, however, also be contacted by only one of the two conductors 12, 120; in this case, the via hole conductor 110′ may possibly be omitted.

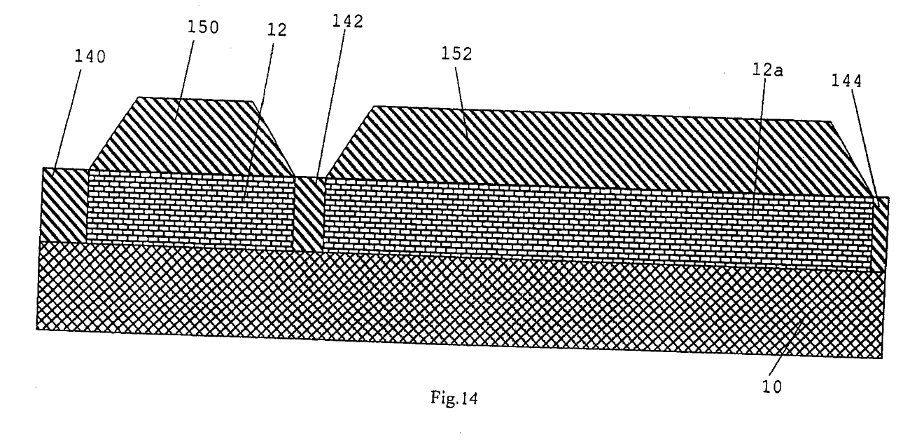

FIG. 14 to 19 show in the form of schematic vertical sectional views various phases of a production method according to a further alternative embodiment of the present invention. This method differs from the first embodiment insofar as, after the production of conductors 12, 12a on the support layer 10, the first dielectric layer 20 is not produced homogeneously in one step, but spaces 140, 142, 144 between the conductors 12, 12a are first filled with a conformal HDP oxide (HDP=High Density Plasma silane oxide), i.e. an amount of HDP oxide is deposited which is just large enough to essentially fill the spaces 140, 142, 144 between the conductors 12, 12a. A characteristic feature of the HDP oxide is that it grows on all edges with the same thickness, i.e. its planarizing effect is only small. HDP oxide is therefore particularly suitable in the present case, since primarily the spaces 140, 142, 144 between the conductors 12, 12a are to be filled, whereas a planarizing effect is not desired. In the course of this process, oxide hats 150, 152 form on top of the conductors 12, 12a. The resultant condition is shown in FIG. 14.

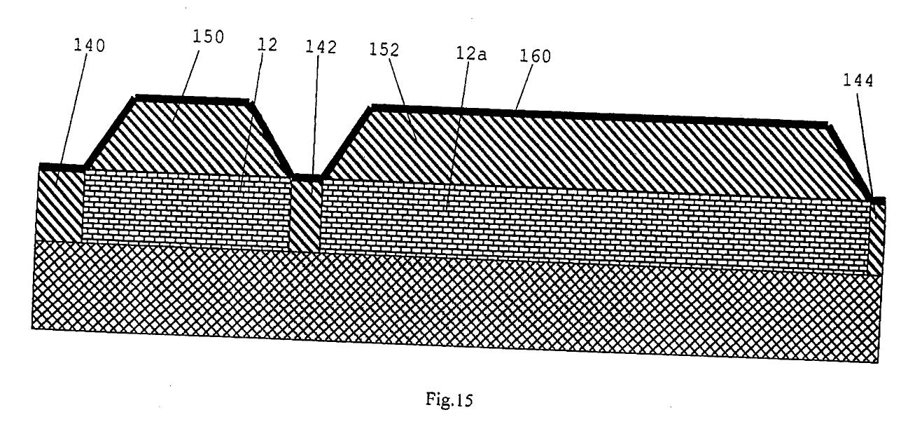

Subsequently, a stop layer 160 is applied to the oxide hats 150, 152 and the oxide in the spaces 140, 142, 144, as shown in FIG. 15. The stop layer 160 serves as an etch stop in a subsequent method step.

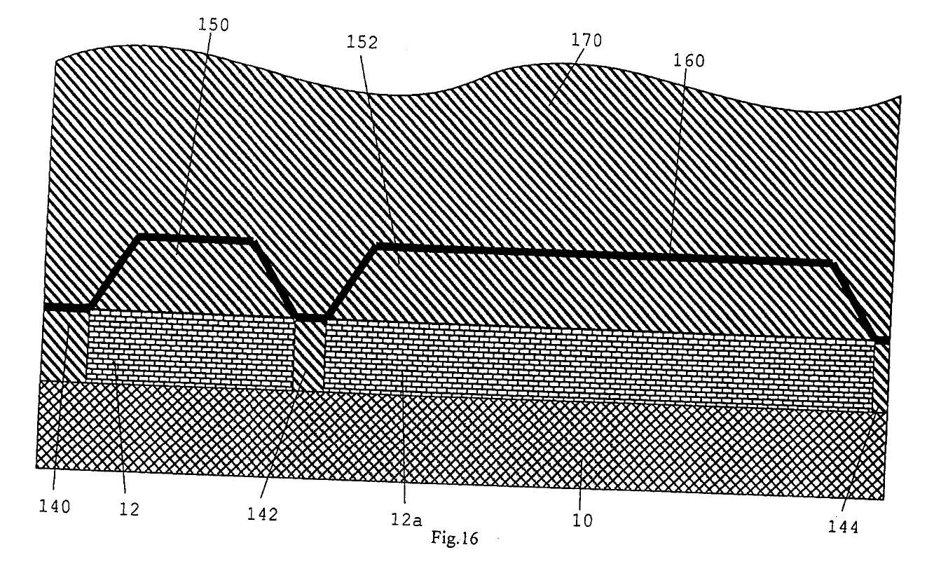

The stop layer 160 has deposited thereon a thick silane layer 170 so as to produce the condition shown in FIG. 16. In contrast to the HDP oxide, which has been used for filling the spaces 140, 142, 144, the silane layer 170 has a stronger planarizing effect.

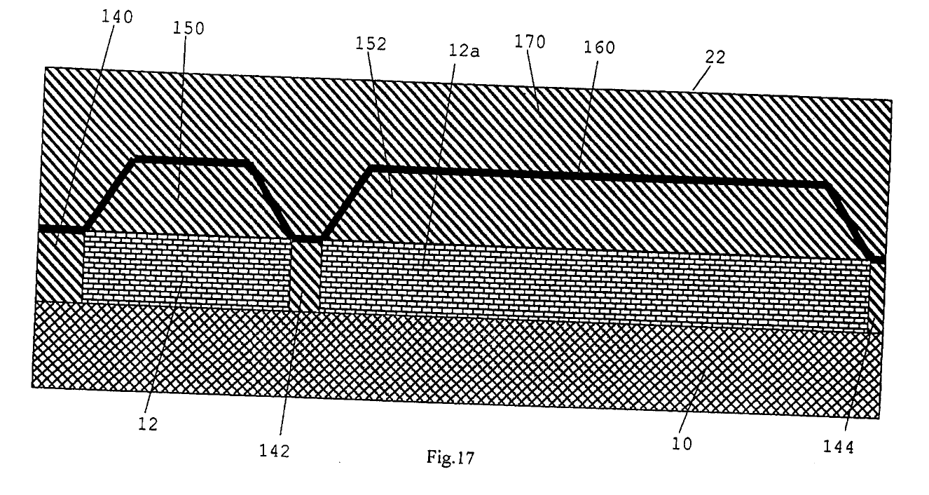

Just as in the case of the first embodiment, the silane layer 170 is then planarized by means of CMP so as to obtain a flat surface corresponding to the surface 22 of the first dielectric layer 20 of the first embodiment. The structure produced in this way is shown in FIG. 17. The oxide hats 150, 152, the stop layer 160 and the silane layer 170 correspond, in common, to the first dielectric layer 20 of the first embodiment.

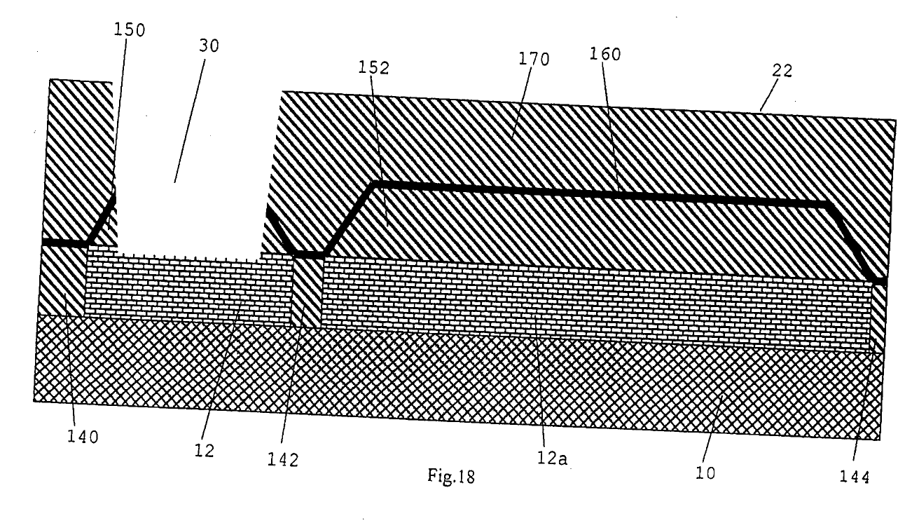

Again as in the case of the first embodiment, a via hole 30 is then etched so as to obtain the structure shown in FIG. 18. The via hole 30 extends from the surface 22 through the silane layer 170, the stop layer 160 and the oxide bump 150 down to the conductor 12.

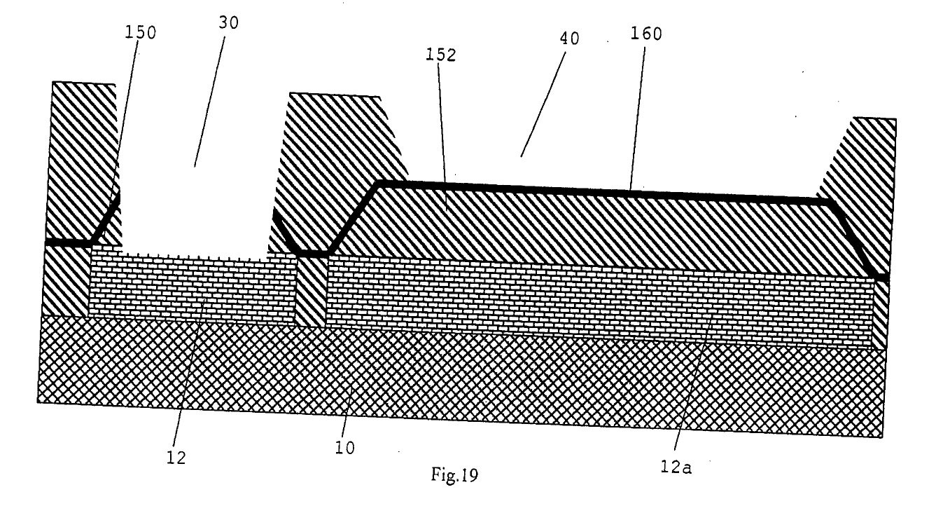

In a further etching step, a recess 40 is etched with an etchant, which is selective with respect to the stop layer 160, so as to obtain the condition shown in FIG. 19. The stop layer 160 serves here as an etch stop so that the recess 40 extends from the surface 22 only down to the stop layer 160. All the following method steps correspond to those of the first embodiment; a renewed description is therefore dispensed with.

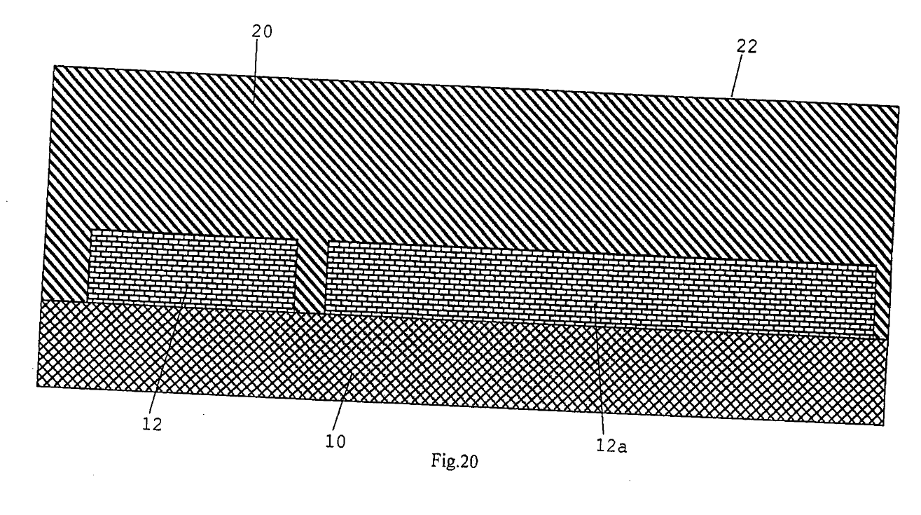

Instead of a using stop layer in the first dielectric layer 20, as shown on the basis of the embodiment represented in FIG. 14 to 19, it is also possible to use a metal plane, such as the conductor 12a, as a stop layer. This is the case in a further alternative embodiment shown on the basis of FIG. 20 to 22. The support layer 10, the conductors 12, a further conductor 12a and the first dielectric layer 20 are produced in the same way as in the first embodiment. The lateral dimensions of the conductor 12a are preferably at least as large as the lateral dimensions of the recess 40 produced later on. The condition obtained after the production of surface 22 by planarizing the first dielectric layer 20 is shown in FIG. 20.

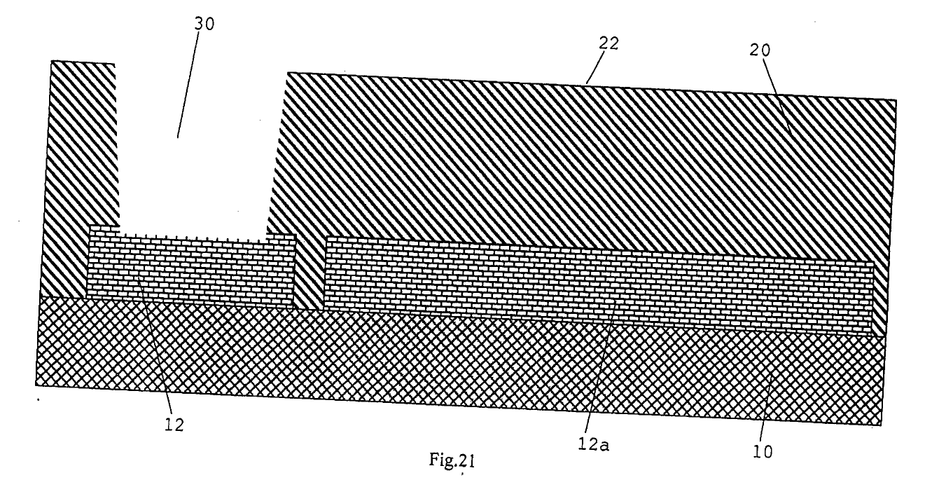

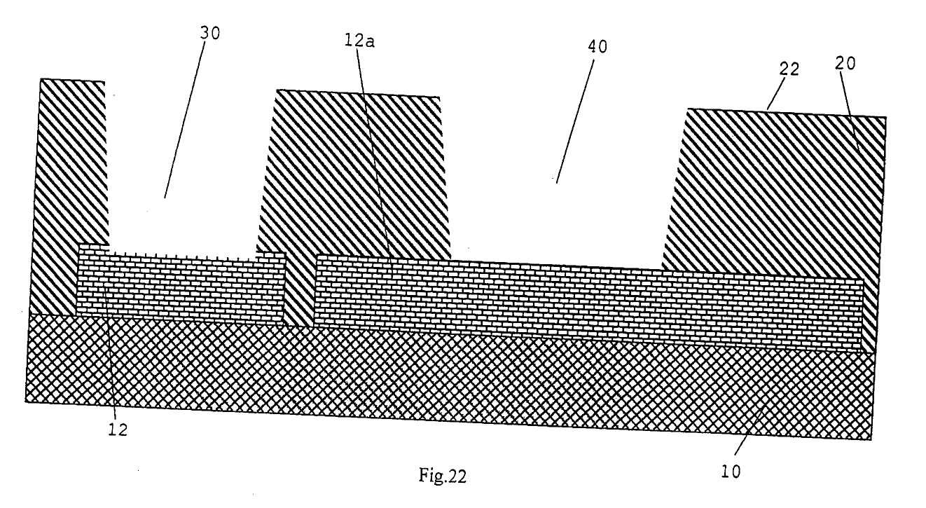

Subsequently, a via hole 30 and a recess 40 are produced in the first dielectric layer 20 so as to successively produce the structures which are shown in FIG. 21 and 22, respectively. Since, in this embodiment, both the via hole 30 as well as the recess 40 extend from the surface 22 of the first dielectric layer 20 down to the conductor 12 and the conductor 12a, respectively, the lithography and/or the etching of the via hole 30 and of the recess 40 can be carried out in a common step in this embodiment. The conductor 12 and the conductor 12a, respectively, serve as an etch stop when this step is carried out.

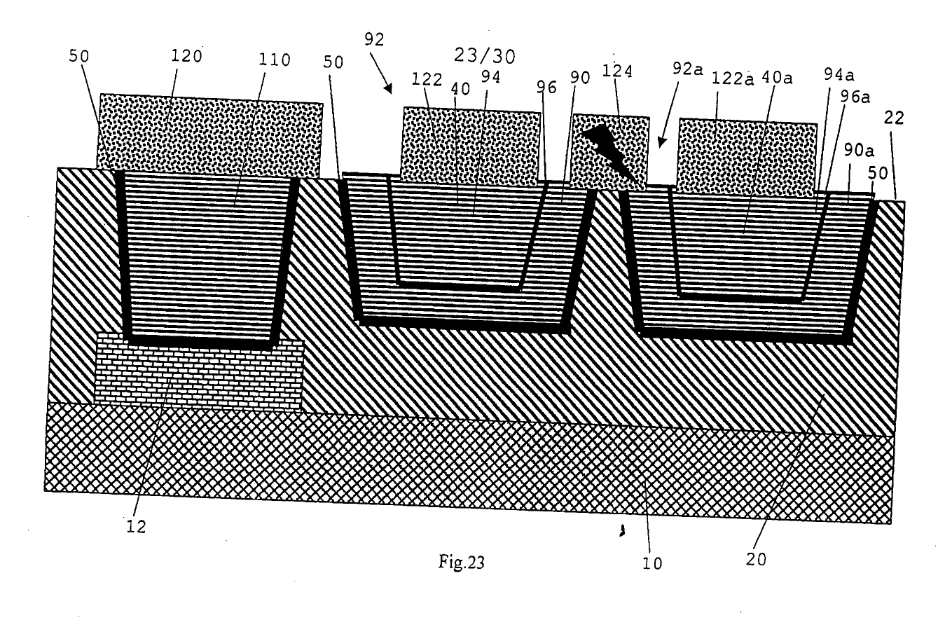

FIG. 23 is a schematic sectional view of two capacitors 92, 92a, which have been produced in accordance with a further alternative embodiment of the present invention. Deviating from the preceding embodiments, two recesses 40, 40a are formed simultaneously or successively, and in these recesses the capacitors 92, 92a consisting of first electrodes 90, 90a and second electrodes 94, 94a are formed in accordance with the method steps of the preceding embodiments, the first electrodes 90, 90a and the second electrodes 94, 94a being spatially separated and electrically insulated by respective portions 96, 96a of a second dielectric layer. The second electrodes are contacted by means of conductors 122, 122a. The first electrodes 90, 90a are contacted in common by a single conductor 124.

The two capacitors 92, 92a are therefore coupled and can e.g. be connected in parallel so as to form an overall capacitance. It is also possible to connect a plurality of such capacitors in parallel; in this case, individual capacitances can be separated, e.g. by means of laser fusing or electric fusing, so as to finely tune the overall capacitance.

When, as shown in FIG. 23, the recesses 40, 40a have a depth which is much larger than the thickness of the first electrodes 90, 90a, the second dielectric layers 96, 96a have vertical portions or portions with a vertical component. This has the effect that the active areas of the electrodes and the capacitances of the capacitors 92, 92a are increased in comparison with a substantially flat structural design of the type existing in the embodiments of FIG. 1 to 22.

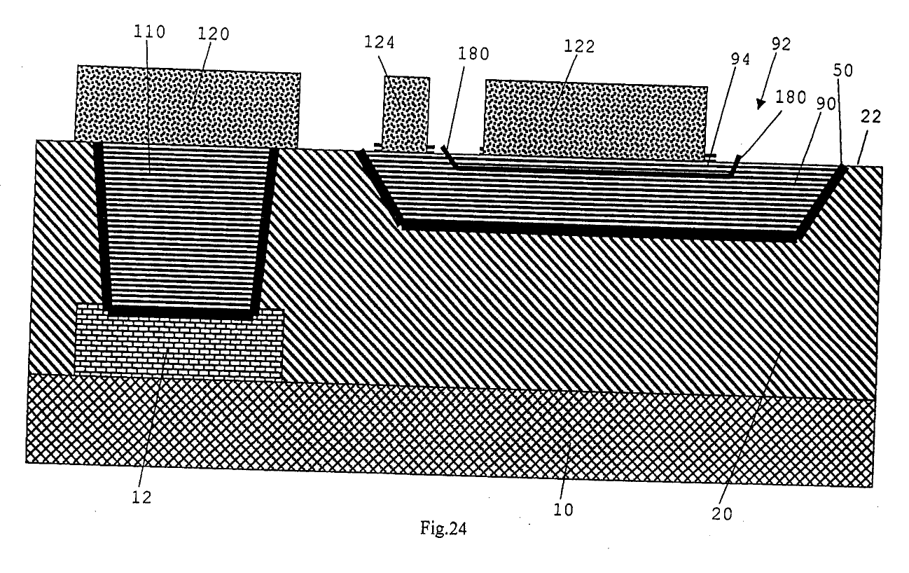

In the case of the preceding embodiments, the danger exists that, during planarizing by means of CMP, a T-bridge may be formed across the edge of the portion 96 of the second dielectric layer 70 between the electrodes 90, 94 of the capacitor 92. Such a T-bridge produces a short circuit between the electrodes 90, 94 and destroys in this way the operability of the capacitor 92. The risk of dishing, i.e. the formation of a tungsten bridge can be reduced e.g. by selective overetching during structuring of the wiring conductors 120, 122, 124, as in the case of the capacitor shown on the basis of FIG. 24, which was produced in accordance with a further alternative embodiment of the present invention. The capacitor 92 shown in this figure essentially corresponds to the capacitor produced in accordance with the first embodiment and shown in FIG. 10. Other than in the case of the first embodiment, part of the first electrode 90 and part of the second electrode 94 of the capacitor 92 are, however, removed, when the wiring conductors 120, 122, 124 are being structured from a full-area conductive layer by means of a photoresist mask and an etching bath, so as to expose an edge 180 of the portion 96 of the second dielectric layer 70 between the first electrode 90 and the second electrode 94. This is done in that an etching medium is used whose removal rate is higher for the T of the electrodes 90, 94 than for the material of the second dielectric layer 70. The resultant structure is the structure shown in FIG. 24, in the case of which the edge 180 of the portion 96 of the second dielectric layer 70 is exposed, i.e. projects relative to the first electrode 90 and the second electrode 94. This guarantees that he electrodes 90, 94 are not short-circuited by a T-bridge.

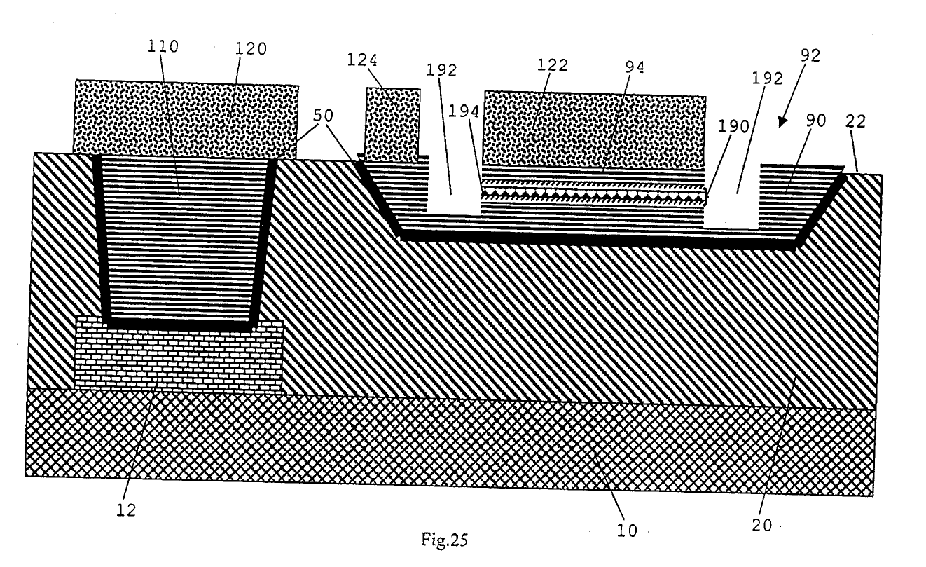

FIG. 25 is a schematic representation of a vertical section through a capacitor 92 in a dielectric layer 20, said capacitor being produced in accordance with a further alternative embodiment of the present invention. This embodiment differs from the preceding ones in that, instead of a single homogeneous thin second dielectric layer 70, a dielectric layer system 190 is formed between the first T-layer 60 and the second T-layer 80. A further difference is to be seen in that a deep trench 192, which fully encloses the second electrode 94, is etched into the first electrode 90, the dielectric layer system 190 and the second electrode 94 in such a way that the inner side wall 194 thereof laterally delimits the dielectric layer system 190. Due to the formation of the trench 192, a T-bridge between the electrodes 90, 94, which may perhaps have been produced during the planarizing step, and the resultant short circuit between the electrodes is reliably removed. Furthermore, the area of the second electrode 94 determining the capacitance of the capacitor 92 is defined by the trench 192 precisely and largely independently of fluctuations in the production process. In addition, the trench 192 can be filled by a dielectric, e.g. an oxide or nitride, so as to protect the dielectric layer system 190 against chemical and physical environmental influences at the locations where it is exposed at the inner wall 194 of the trench 192.

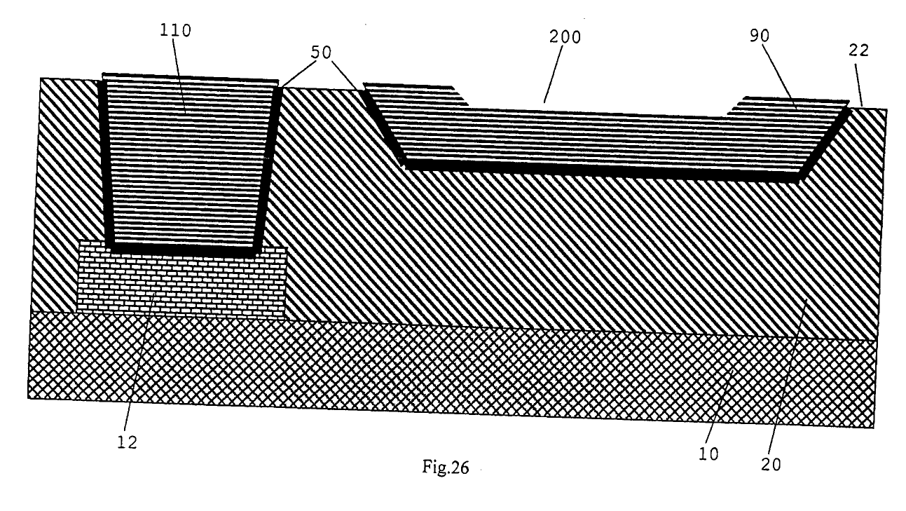

FIG. 26 to 31 show in schematic vertical sectional views a further alternative embodiment of the present invention. The first method steps up to an including the production of the first T-layer 60 are identical with those of the first embodiment.

The present embodiment differs from the first embodiment insofar as an additional first planarizing step is carried out already subsequent to the production of the first T-layer 60, which is shown in FIG. 5, so as to obtain the structure shown in FIG. 26. By means of this additional planarizing step, the first T-layer 60 is removed outside of the via hole 30 and the recess 40 already immediately after its production, i.e. essentially above a plane which is defined by the original surface 22 of the dielectric layer 20. In so doing, polishing is carried out to such an extent that the intermediate layer 50 is removed in all areas outside of the via hole 30 and the recess 40. The T-blocks in the via hole 30 and in the recess 40 are slightly higher than the first dielectric layer, as indicated in FIG. 26. It follows that the via hole conductor 110 and the first electrode 90 already exist essentially in their final shape, spatially separated and electrically insulated from one another. Since the thickness of the first electrode 90 is smaller than the depth of the recess 40, the first electrode 90 is provided with a recess 200 which will accommodate the second dielectric layer and the second electrode later on.

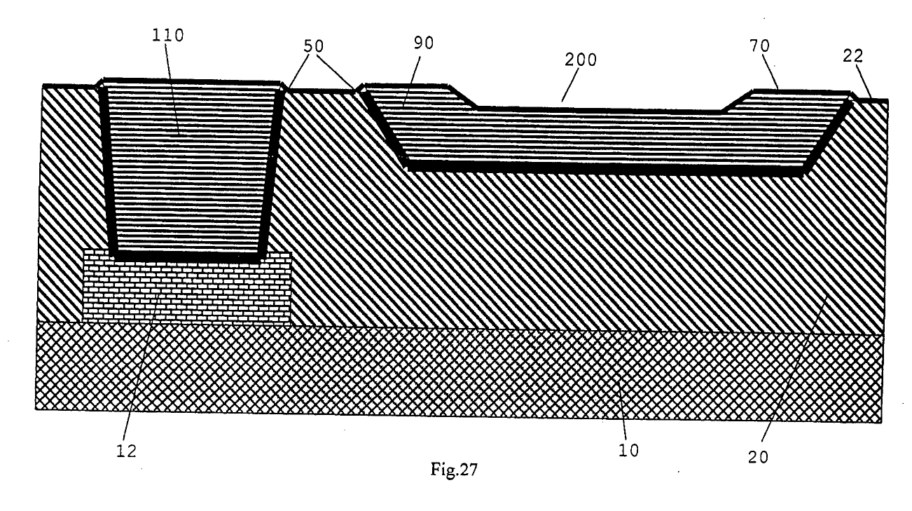

As in the case of the preceding embodiments, a second dielectric layer 70 is then applied to the surface 22 of the dielectric layer 20, the first electrode 90 and the via hole conductor 110 over the full area thereof of these components, so as to obtain the structure shown in FIG. 27.

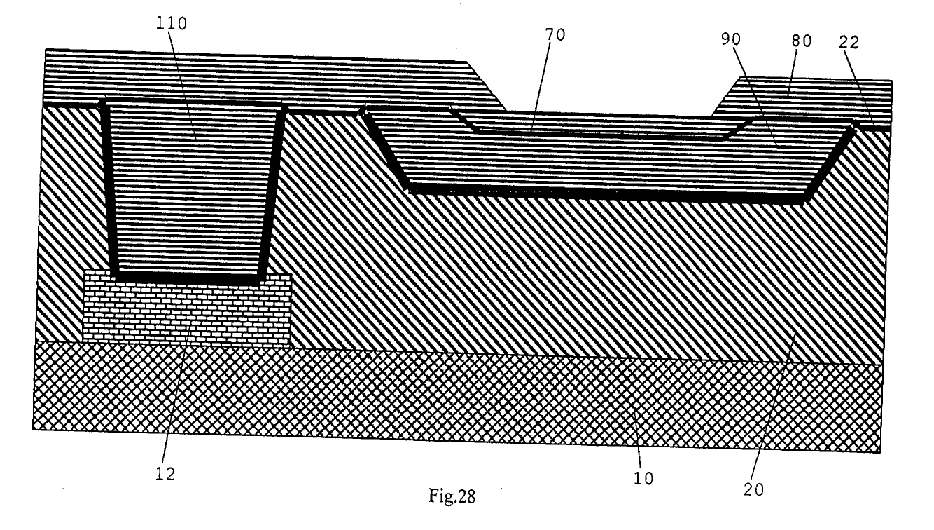

The second dielectric layer 70 has deposited thereon a second T-layer 80, again over the full area thereof, so as to obtain the structure shown in FIG. 28.

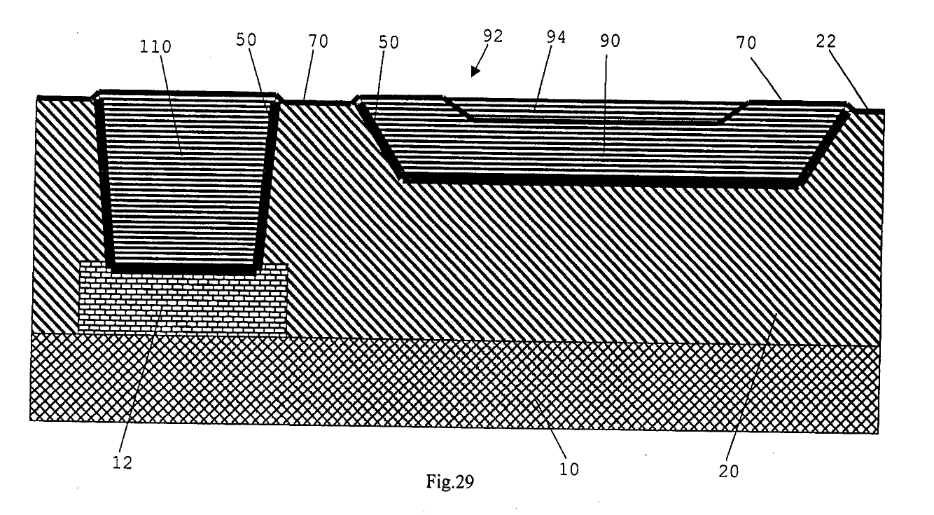

In a subsequent planarizing step, which corresponds essentially to the planarizing step of the preceding embodiments, planarizing is carried out down to the second dielectric layer 70, so as to obtain the structure shown in FIG. 29. In the course of this process, the second electrode 94 is produced from the second T-layer 80, which remains only in the recess 200 within the first electrode 90. It follows that the dielectric layer 70 serves in this embodiment as a stop layer for the second planarizing step.

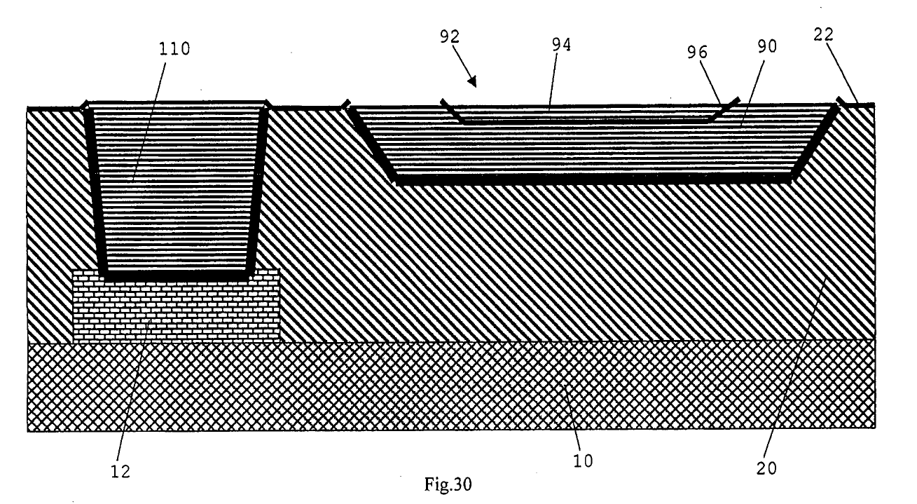

By means of defined overpolishing or an additional wet-cleaning step, the second dielectric layer 70 is removed with exception of a portion 96 between the electrodes 90, 94. This results in the structure which is shown in FIG. 30 and at the surface of which the via hole conductor 110, the first electrode 90 and the second electrode 94 are exposed. As in the case of the preceding embodiments, the via hole conductor 110 and the electrodes 90, 94 of the capacitor 92 can then be contacted by means of wiring conductors.

One advantage of the seventh embodiment of the method according to the present invention, which is shown on the basis of FIG. 26 to 30, is that it is also compatible with a very hard second dielectric layer 70 which cannot easily be removed and penetrated, respectively, in a polishing or planarizing step. On the other hand, the second dielectric layer 70 represents in this case a reliable stop layer for the second planarizing step.

In all embodiments, the first dielectric layer 20 can be a first layer bordering directly on a component layer of a semiconductor structure, the support layer 10 representing the component layer and the via hole 30 reaching preferably directly down to a component in the component layer 10, i.e. down to a contact of the component, instead of reaching down to the conductor 12. However, the present invention may just as well be used for producing a capacitor in a dielectric layer 20 spaced from a component layer of a semiconductor structure; the first dielectric layer 20 may then be located between two arbitrary wiring planes or it may also be the uppermost dielectric layer.

A special advantage of the material T used in the embodiments as a material for the via hole conductor 110 and the electrodes 90, 94 is that it is excellently suitable for polishing. If a via hole 30 is provided, a use of T for the electrodes 90, 94 is also advantageous insofar as the first electrode 90 can be formed in one step together with the via hole conductor 110. The production method according to the present invention is, however, also adapted to be used with other materials for the electrodes 90, 94, provided that these materials permit planarization with sufficient precision and reliability. Furthermore, different conductive materials can be used for the first electrode 90 and the second electrode 94.

Especially if the depth of the recess 40 is chosen such that it is much larger than the thickness of the first conductive layer 60, a capacitor 92 is obtained with pot-shaped electrodes 90, 94 and a pot-shaped portion 96 of the second dielectric layer 70 between the electrodes 90, 94, as has already been shown in FIG. 23. In this case, the portion 96 of the second dielectric layer 70 comprises not only a surface parallel to the surface 22 of the first dielectric layer 20 but also an additional vertical surface area. This has the effect that the area of the portion 96 of the second dielectric layer 70 determining the capacitance of the capacitor is enlarged in comparison with a substantially flat capacitor in a shallow recess 40 as well as in comparison with a conventional capacitor. This means that the space available is utilized more effectively.

The method according to the present invention permits in an advantageous manner the simultaneous production of one or of a plurality of capacitors and of one or of a plurality of via hole conductors in the same dielectric layer, said via hole conductors being directly or indirectly connected to the capacitors or being electrically insulated therefrom. The method according to the present invention can, however, also be used and is also advantageous in cases in which a simultaneous production of a via hole conductor does not take place. Furthermore, it is also possible to simultaneously produce a plurality of capacitors, which are connected in parallel e.g. for forming an overall capacitance; for finely tuning the overall capacitance, individual ones of these capacitors can be separated by means of laser fusing.

While this invention has been described in terms of several preferred embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. A method of producing a capacitor in a first dielectric layer, said method comprising the following steps:
forming a recess in a surface of the first dielectric layer;
producing a first conductive layer on the surface of the first dielectric layer and in the recess;
producing a second dielectric layer on the first conductive layer, the sum of a thickness of the first conductive layer and of a thickness of the second dielectric layer in the recess being smaller than a depth of said recess;
producing a second conductive layer on the second dielectric layer;
planarizing the thus formed layer structure so as to obtain the capacitor; and
producing a trench which completely surrounds the second electrode laterally and extends to the first conductive layer.

2. The method according to claim 1, further comprising the following step:
filling the trench with a dielectric.

3. The method according to claim 1, wherein the step of planarizing includes a step of removing the first and second conductive layers and the second dielectric layer outside of the recess down to a plane defined by the surface of the first dielectric layer.

4. The method according to claim 1, wherein producing the second conductive layer comprises producing the second conductive layer without first exposing the second dielectric layer to any of the group consisting of a photoresist mask, an exposure mask, solvent or etching bath.

5. The method of claim 1 wherein producing the second conductive layer occurs directly after producing the second dielectric layer.

6. The method of claim 1 further comprising the steps of:
producing a third conductive layer over the capacitor;
selectively etching the third conductive layer to produce at least one contact coupled to at least one of the group consisting of the first conductive layer and the second conductive layer.

7. A method of producing a capacitor in a substrate, said method comprising the following steps:
a) forming a recess in a surface of a first dielectric layer;
b) producing a first conductive layer on the surface of the first dielectric layer and in the recess;
c) producing a second dielectric layer on the first conductive layer while said substrate is disposed in a receptacle, the sum of a thickness of the first conductive layer and of a thickness of the second dielectric layer in the recess being smaller than a depth of said recess;
d) producing a second conductive layer on the second dielectric layer prior to removing the substrate from the receptacle, the second conductive layer disposed at least in part within the recess; and
e) planarizing the thus formed layer structure so as to obtain the capacitor.

8. The method of claim 7 wherein step d) further comprises producing the second conductive layer without first contacting the second dielectric layer with any of the group consisting of a photoresist mask, an exposure mask, solvent or etching bath.

9. The method of claim 7 wherein step d) occurs directly after step c).

10. The method of claim 7 wherein step b) further comprises producing the first conductive layer such that the first conductive layer includes Tungsten.

11. The method of claim 7 wherein step c) further comprises producing the second dielectric layer such that the second dielectric layer has a thickness of one to three atomic layers.

12. The method of claim 7 wherein the step of planarizing includes a step of removing the first and second conductive layers and the second dielectric layer outside of the recess down to a plane defined by the surface of the first dielectric layer.

13. The method of claim 7 further comprising the steps of:
producing a third conductive layer over the capacitor;
selectively etching the third conductive layer to produce at least one contact coupled to at least one of the group consisting of the first conductive layer and the second conductive layer.

14. A method of producing a capacitor in a substrate, said method comprising the following steps:
a) forming a recess in a surface of a first dielectric layer;
b) producing a first conductive layer on the surface of the first dielectric layer and in the recess;
c) producing a second dielectric layer on the first conductive layer, the sum of a thickness of the first conductive layer and of a thickness of the second dielectric layer in the recess being smaller than a depth of said recess;
d) producing a second conductive layer on the second dielectric layer, the second conductive layer disposed at least in part within the recess; and
e) planarizing the thus formed layer structure so as to obtain the capacitor.

15. The method of claim 14 wherein step d) further comprises producing the second conductive layer without first exposing the second dielectric layer to any of the group consisting of a photoresist mask, an exposure mask, solvent or etching bath.

16. The method of claim 14 wherein step d) occurs directly after step c).

17. The method of claim 14 wherein step b) further comprises producing the first conductive layer such that the first conductive layer includes Tungsten.

18. The method of claim 14 wherein step c) further comprises producing the second dielectric layer such that the second dielectric layer has a thickness of one to three atomic layers.

19. The method of claim 14 wherein the step of planarizing includes a step of removing the first and second conductive layers and the second dielectric layer outside of the recess down to a plane defined by the surface of the first dielectric layer.

20. The method of claim 14 further comprising the steps of:
producing a third conductive layer over the capacitor;
selectively etching the third conductive layer to produce at least one contact coupled to at least one of the group consisting of the first conductive layer and the second conductive layer.
